(19) United States
(12) Patent Application Publication
(10) Pub. No.: US 2025/0087651 A1
(43) Pub. Date: Mar. 13, 2025

(54) SEMICONDUCTOR PACKAGE

(71) Applicant: Samsung Electronics Co., Ltd., Suwon-si (KR)

(72) Inventors: Junghoon Kang, Suwon-si (KR); Daegon Kim, Suwon-si (KR)

(21) Appl. No.: 18/646,858

(22) Filed: Apr. 26, 2024

(30) Foreign Application Priority Data
Sep. 11, 2023 (KR) 10-2023-0120488

(51) Int. Cl. H01L 25/16; H01L 23/00; H01L 23/04; H01L 23/48; H01L 23/498

(52) U.S. Cl. CPC H01L 25/167; H01L 23/04; H01L 23/481; H01L 23/49816; H01L 24/08; H01L 2224/08145

(57) ABSTRACT

A semiconductor package includes a package substrate including a first surface and a second surface opposite the first surface, a die disposed on the first surface of the package substrate, a stack structure disposed on the first surface of the package substrate and spaced apart from the die in a horizontal direction, and a socket disposed between the first surface of the package substrate and the stack structure and coupling the package substrate and the stack structure to each other, wherein the stack structure includes a plurality of optical integrated circuit chips stacked vertically with each other.

### CROSS-REFERENCE TO RELATED APPLICATIONS

This application is based on and claims priority under 35 U.S.C. § 119 to Korean Patent Application No. 10-2023-0120488, filed on Sep. 11, 2023, in the Korean Intellectual Property Office, the disclosure of which is incorporated by reference herein in its entirety.

### BACKGROUND

Aspects of the inventive concept relate to a semiconductor package, and more specifically, to a semiconductor package including an optical integrated circuit.

The advantages of semiconductor packages are increasingly more used to improve the functionality of electronic devices and integrate components. A semiconductor package allows various integrated circuits, such as memory chips or logic chips, to be mounted on a package substrate. Recently, in an environment where data traffic is increasing in data centers and communication infrastructure, research on semiconductor packages including optical integrated circuits continues.

### SUMMARY

Aspects of the inventive concept provide a semiconductor package having an improved integration degree and speed.

Aspects of the inventive concept also provide a semiconductor package in which an optical integrated circuit chip is easily replaceable.

Aspects of the inventive concept also provide a semiconductor package in which fastening between an optical integrated circuit and a package substrate is easy.

In addition, objectives to be addressed or solved by the inventive concept are not limited to the above-mentioned ones, and other objectives may be clearly understood by those skilled in the art from the description below.

According to an aspect of the inventive concept, a semiconductor package includes a package substrate including a first surface and a second surface opposite the first surface, a die disposed on the first surface of the package substrate, a stack structure disposed on the first surface of the package substrate and spaced apart from the die in a horizontal direction, and a socket disposed between the first surface of the package substrate and the stack structure and coupling the package substrate and the stack structure to each other, wherein the stack structure includes a plurality of optical integrated circuit chips stacked vertically with each other.

According to another aspect of the inventive concept, a semiconductor package includes a package substrate including a first surface and a second surface opposite the first surface, a die disposed on the first surface of the package substrate, external connection terminals disposed on the second surface of the package substrate, a stack structure disposed on the first surface of the package substrate and spaced apart from the die in a horizontal direction, the stack structure including a plurality of optical integrated circuit chips stacked vertically with each other, a socket disposed between stack structure and the first surface of the package substrate and, and coupling the package substrate to the stack structure, and an optical input/output connector coupled to each of the optical integrated circuit chips.

According to another aspect of the inventive concept, a semiconductor package includes a package substrate including a first surface and a second surface opposite the first surface, a die disposed on the first surface of the package substrate and connected to the package substrate through a connection terminal, a stack structure disposed on the first surface of the package substrate and spaced apart from the die in a horizontal direction, a cover covering at least a portion of the stack structure, an optical input/output connector spaced apart from the die with the stack structure therebetween, and a socket disposed between the first surface of the package substrate and the stack structure and coupling the package substrate and the stack structure to each other, wherein the stack structure includes a plurality of optical integrated circuit chips stacked vertically with each other, and an electronic integrated circuit chip on an uppermost optical integrated circuit chip among the plurality of optical integrated circuit chips, wherein the uppermost optical integrated circuit chip among the plurality of optical integrated circuit chips and the electronic integrated circuit chip are electrically connected to each other.

### BRIEF DESCRIPTION OF THE DRAWINGS

Embodiments will be more clearly understood from the following detailed description taken in conjunction with the accompanying drawings in which:

FIG. 1 is a perspective view illustrating a semiconductor package according to an embodiment;

FIG. 2 is a plan view illustrating the semiconductor package of FIG. 1, illustrating a first surface of a package substrate according to an embodiment;

FIG. 3 is a plan view illustrating the semiconductor package of FIG. 1, illustrating a second surface of the package substrate according to an embodiment;

FIG. 4 is a cross-sectional view taken along line A-A′ of FIG. 2 according to an embodiment;

FIG. 5 is a perspective view illustrating a socket, a stack structure, and a cover, according to an embodiment;

FIG. 6 is a perspective view illustrating a semiconductor package according to an embodiment;

FIG. 7 is a plan view illustrating the semiconductor package of FIG. 6, illustrating a first surface of a package substrate according to an embodiment;

FIG. 8 is a perspective view illustrating a semiconductor package according to an embodiment;

FIG. 9 is a plan view illustrating the semiconductor package of FIG. 8, illustrating a first surface of a package substrate according to an embodiment;

FIG. 10 is a cross-sectional view taken along line B-B′ of FIG. 9 according to an embodiment;

FIG. 11 is a perspective view illustrating a cover according to an embodiment;

FIG. 12 is a perspective view illustrating a semiconductor package according to an embodiment; and

FIG. 13 is a perspective view illustrating an intermediate substrate and an optical input/output port, according to an embodiment.

### DETAILED DESCRIPTION OF THE EMBODIMENTS

As the inventive concept allows for various changes and numerous embodiments, particular embodiments will be illustrated in the drawings and described in detail in the written description. However, this is not intended to limit the present embodiments to the specific disclosure herein.

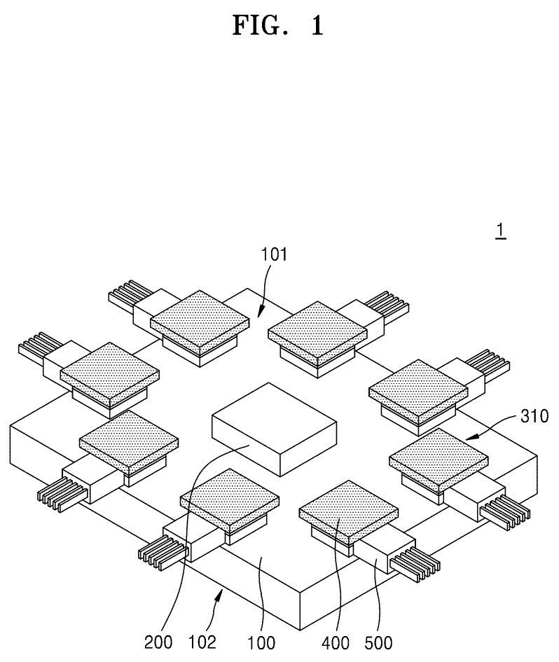

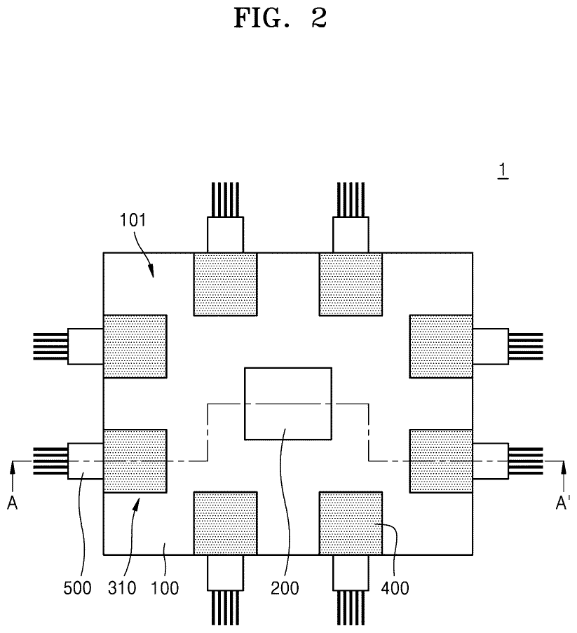

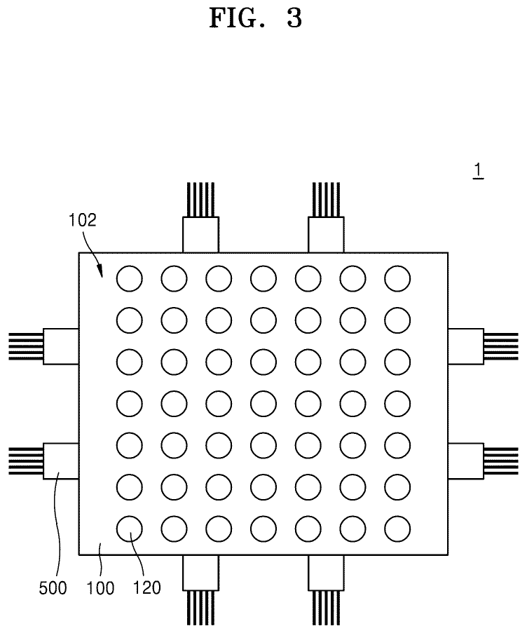

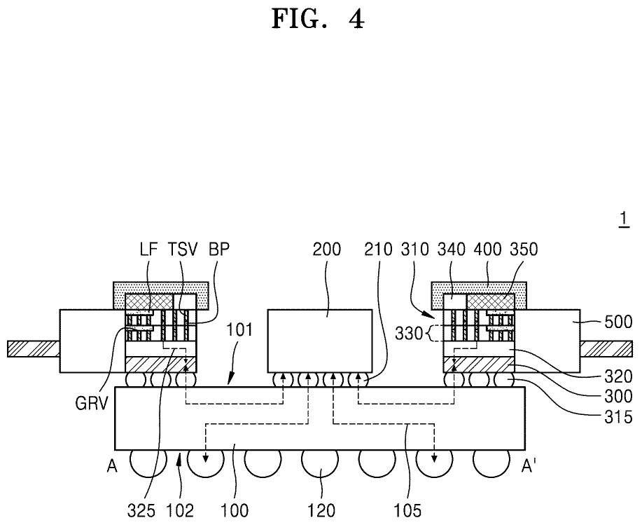

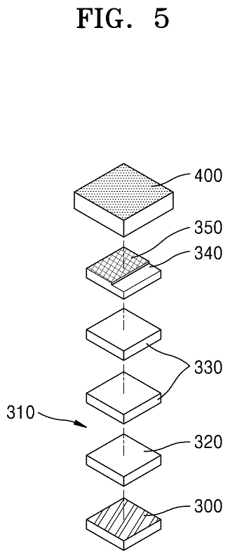

FIG. 1 is a perspective view illustrating a semiconductor package according to an embodiment. FIG. 2 is a plan view illustrating the semiconductor package of FIG. 1, illustrating a first surface of a package substrate. FIG. 3 is a plan view illustrating the semiconductor package of FIG. 1, illustrating a second surface of the package substrate. FIG. 4 is a cross-sectional view taken along line AA′ of FIG. 2 according to an embodiment. FIG. 5 is a perspective view illustrating a socket, a stack structure, and a cover, according to an embodiment.

Referring to FIGS. 1 to 4, a semiconductor package 1 may include a package substrate 100, a die 200, a socket 300, a stack structure 310, a cover 400, and an optical input/output device 500.

The package substrate 100 may include, for example, a printed circuit board (PCB). As an example, the package substrate 100 may include a core substrate or a coreless substrate. The package substrate 100 may include a plurality of embedded insulating layers and conductive routing. Electrical passages formed through conductive routing may be referred to as first electrical passages 105. The first electrical passages 105 are illustrated as dashed lines for simplicity. However, the first electrical passages 105 may represent conductive features of the package substrate 100 (e.g., traces, vias, pads, etc.). The package substrate 100 may include a first surface 101 and a second surface 102 opposite the first surface 101. The first surface 101 may be an upper surface of the package substrate 100 and may be a portion where the die 200 and the stack structure 310 are disposed. The second surface 102 may be a lower surface of the package substrate 100 and may be a portion where an external connection terminal 120 is disposed.

The external connection terminal 120 may be disposed on the second surface 102 of the package substrate 100. The external connection terminal 120 may be configured to connect the package substrate 100 to external devices, such as a mother board. The package substrate 100 may be mechanically and/or electrically connected to an external device through the external connection terminal 120. A plurality of external connection terminals 120 may be provided. Each of the plurality of external connection terminals 120 may be electrically connected to the die 200 and/or the stack structure 310 through a corresponding one of the first electrical passages 105 inside the package substrate 100. The external connection terminals 120 may include or be solder balls, copper pillars, or the like.

The die 200 may be disposed on the first surface 101 of the package substrate 100. The die 200 may be electrically and mechanically coupled to the package substrate 100 through the first connection terminal 210. A plurality of first connection terminals 210 may be provided. In an embodiment, the die 200 may include a logic chip such as an application specific integrated circuit (ASIC) or an application processor (AP). However, this only corresponds to an embodiment, and the type of die 200 is not limited thereto. Although only one die 200 is illustrated in FIGS. 1, 2, and 4, in other embodiments, two or more dies 200 may be included in the semiconductor package 1. This may vary depending on the design of the semiconductor package 1 to be implemented. The first connection terminals 210 may include or be solder bumps and/or solder balls.

The stack structure 310 may be laterally spaced apart from the die 200 and disposed on the first surface 101 of the package substrate 100. A plurality of stack structures 310 may be provided. The plurality of stack structures 310 may be arranged in an annular shape, with the die 200 in a center. For example, eight stack structures 310 may be provided as illustrated in FIG. 2. Eight stack structures 310 may be arranged two at a time on each side of the package substrate 100. However, in the inventive concept, the number and planar arrangement of the stack structures 310 is not limited thereto. The stack structures 310 may be provided in a number of eight or fewer or eight or more, and may be disposed on only one side of the die 200 from a plan view. This may vary depending on the design of the semiconductor package 1 to be implemented. Hereinafter, one stack structure 310 will be described, but the description below may also be applied to other stack structures 310.

As illustrated in FIG. 5, the stack structure 310 may include an intermediate substrate 320, an optical integrated circuit chip 330, an electronic integrated circuit chip 340, and a clamp 350. As an example, the intermediate substrate 320 may include an interposer or a redistribution layer (RDL). The intermediate substrate 320 may include a plurality of embedded insulating layers and conductive routing. Electrical passages inside the intermediate substrate 320 formed through conductive routing may be referred to as second electrical passages 325. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). The second electrical passages 325 are illustrated as dashed lines for simplicity. However, the second electrical passages 325 may represent conductive features of the intermediate substrate 320 (e.g., traces, vias, pads, etc.). The intermediate substrate 320 may be omitted. When the intermediate substrate 320 is omitted, a lowermost optical integrated circuit chip 330 may be directly mechanically and electrically coupled to the socket 300. This may vary depending on the design of the semiconductor package 1 to be implemented.

The optical integrated circuit chip 330 may be disposed on the intermediate substrate 320. The optical integrated circuit chip 330 may include a circuit in which an optical integrated circuit element and an electrical integrated circuit element are combined. The optical integrated circuit chip 330 may refer to a device for converting optical signals to electrical signals or/and converting electrical signals to optical signals. The optical integrated circuit chip 330 may include a through via TSV, a bonding pad BP, and a groove GRV.

The through via TSV may penetrate a body of the optical integrated circuit chip 330. The body may be a portion that includes a circuit in which an optical integrated circuit element and an electrical integrated circuit element are combined. A single or plural number of through vias TSV may be provided. The through vias TSV may include or be formed of a conductive metal.

The bonding pad BP may be disposed on an upper surface and/or a lower surface of the optical integrated circuit chip 330. A plurality of bonding pads BP may be provided. The plurality of bonding pads BP may include metal such as copper or aluminum.

The groove GRV may be a portion recessed downward from the upper surface of the optical integrated circuit chip 330. The groove may also be described as a recess. The groove GRV may be formed on an edge portion of the optical integrated circuit chip 330. The edge portion refers to a portion of the optical integrated circuit chip 330 that is closer to the optical input/output device 500 than to the die 200. An optical fiber included in the optical input/output device 500 may be mechanically and optically connected to the optical integrated circuit chip 330 through the groove GRV. A plurality of optical fibers may be provided in the groove. Each of the plurality of optical fibers may be connected to a corresponding optical integrated circuit chip 330. The plurality of optical fibers may be spaced apart from each other in a vertical direction.

The plurality of optical integrated circuit chips 330 may be provided. The plurality of optical integrated circuit chips 330 may be sequentially stacked in a vertical direction. FIGS. 4 and 5 illustrate that the number of optical integrated circuit chips 330 is two, but the inventive concept is not limited thereto, and three or more optical integrated circuit chips 330 may be provided. Also, only one optical integrated circuit chip 330 may be provided. This may vary depending on the design of the semiconductor package 1 to be implemented. Two optical integrated circuit chips 330 adjacent to each other above and below may be mechanically and electrically coupled to each other through the bonding pads BP. In detail, the bonding pads BP on the lower surface of an upper optical integrated circuit chip 330 and the bonding pads BP on the upper surface of the lower optical integrated circuit chip may contact each other, respectively. As an example, two optical integrated circuit chips 330 may be hybrid-bonded to each other. Hybrid bonding refers to bonding where the bonding pads BP disposed in upper and lower optical integrated circuit chips 330 contact each other, and at the same time, passivation layers (not shown) disposed in the upper and lower optical integrated circuit chips 330 contact each other, so that one optical integrated circuit chip 330 and another optical integrated circuit chip 330 are bonded to each other. According to this method, the optical integrated circuit chips 330 may be sequentially stacked in the vertical direction.

The electronic integrated circuit chip 340 and the clamp 350 may be arranged on the uppermost optical integrated circuit chip 330. The electronic integrated circuit chip 340 may include a circuit having electrical integrated circuit elements. The electronic integrated circuit chip 340 may be contrasted with the optical integrated circuit chip 330 in that the electronic integrated circuit chip 340 includes only circuits with electrical integrated circuit elements. The electronic integrated circuit chip 340 may be mechanically and electrically connected to the uppermost optical integrated circuit chip 330. The clamp 350 may perform a function to help ensure that optical fibers coming from the optical input/output device 500 are properly fixed to the stack structure 310. The clamp 350 may be arranged on an edge portion of the stack structure 310.

The socket 300 may be arranged between the package substrate 100 and the stack structure 310. The socket 300 may be arranged only on the first surface 101 of the package substrate 100. The socket 300 may mechanically and electrically couple the package substrate 100 and the stack structure 310 to each other. The socket 300 may include, for example, a land grid array (LGA) type. When the socket 300 is an LGA type, the socket 300 may include pins rising in a direction toward the stack structure 310, and pads (e.g., contacts) that may be electrically connected to the pins may be arranged on a lower surface of the intermediate substrate 320 of the stack structure 310. Alternatively, the socket 300 may include, for example, a pin grid array (PGA) type. When the socket 300 is a PGA type, pins rising toward the socket 300 may be disposed on the lower surface of the intermediate substrate 320 of the stack structure 310, and the socket 300 may include grooves (e.g., contacts) that may accommodate the pins of the intermediate substrate 320. When the intermediate substrate 320 is not used, the pins or grooves/pads may be formed on the lowermost optical integrated circuit chip 330 of the stack structure 310.

The socket 300 may be mechanically and electrically connected to the package substrate 100 through second connection terminals 315. The second connection terminals 315 may include solder bumps and/or solder balls. Alternatively, the second connection terminals 315 may be omitted and the socket 300 may be directly attached to the first surface 101 of the package substrate 100. In this embodiment, hybrid bonding or some other type of surface bonding may be used to electrically and physically connect the socket 300 to the first surface 101 of the package substrate 100.

Since the socket 300 is disposed only on the first surface 101, it may be easy to couple the package substrate 100 with an external device such as a motherboard. In addition, as the socket 300 is disposed, there is no need to use a solder ball to directly couple the stack structure 310 including the optical integrated circuit chip 330, to the package substrate 100, and thus, exposure of the optical integrated circuit chip 330 to high temperature required to reflow solder balls may be prevented. In addition, since the socket 300 is easy to couple to and separate from the stack structure 310, if the stack structure 310 is damaged, or performance deteriorates, and/or if there is a product that is better compatible with the die 200 as a replacement for the stack structure 310, the stack structure 310 may be easily replaced. This means that fastening between the optical integrated circuit chip 330 and the package substrate 100 is easy, and replacement of the optical integrated circuit chip 330 is easy. Additionally, since a plurality of optical integrated circuit chips 330 may be provided, the integration degree and speed of the semiconductor package 1 may be improved. Therefore, by attaching a socket 300 to the package substrate 100 using solder bumps or balls, and then attaching the stack structure 310 to the socket 300 using, for example, pins, the stack structure 310 may be replaceable or interchangeable while keeping the socket 300 attached to the package substrate 100 using the connection terminals 315.

The cover 400 may cover a portion of the stack structure 310. In an embodiment, the cover 400 may include a bolt type cover. The cover 400 may be coupled to the socket 300 through a bolt, but is not limited thereto. The cover 400 may contain various materials. For instance, the cover 400 may include or be formed of metallic materials such as iron and aluminum, or it may also include or be formed of polymer materials such as plastic, but is not limited thereto. The materials that the cover 400 can contain may vary.

The cover 400 may fully contact and cover a top surface of the stack structure 310 including a top surface of the electronic integrated circuit chip 340 and clamp 350, and may also cover and contact side surfaces of the electronic integrated circuit chip 340 and clamp 350. For example, the cover 400 may have an open box shape.

The optical input/output device 500 may be connected to the stack structure 310 and may extend away from the package substrate 100. The optical input/output device 500 may be spaced apart from the die 200 with the stack structure 310 therebetween. The optical input/output device 500 may include optical fibers entering the optical input/output device 500 from the outside and optical fibers going out from (e.g., exiting) the optical input/output device 500 and extending to the stack structure 310. Each of the optical fibers going out from the optical input/output device 500 to the stack structure 310 may be disposed within one of the plurality of grooves GRV. The optical fibers may be connected to the optical integrated circuit chips 330 through the grooves GRV. Each of the optical fibers going out from the optical input/output device 500 to the stack structure 310 may be surrounded by an optical film LF within the grooves GRV. The optical film LF may fill the remaining space within the groove GRV except for the optical fibers. The optical film LF may perform a function of physically protecting the optical fibers from the outside and helping the optical fibers to be optically combined with the optical integrated circuit chip 330. The optical film LF may include or be formed of an optical resin material such as acrylic resin, epoxy resin, or polyurethane resin.

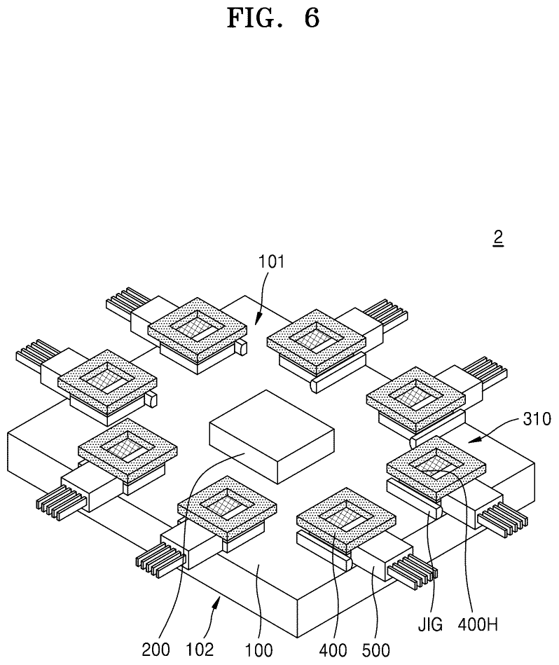

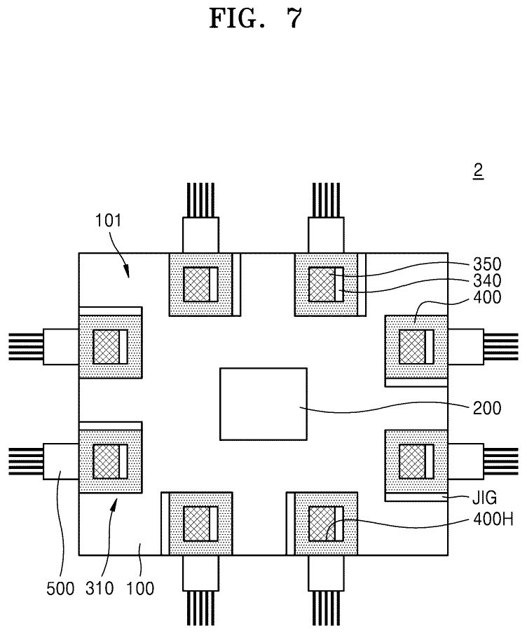

FIG. 6 is a perspective view illustrating a semiconductor package according to an embodiment. FIG. 7 is a plan view illustrating the semiconductor package of FIG. 6, illustrating a first surface of a package substrate.

Most of the components constituting a semiconductor package 2 described below and the materials constituting the components are substantially the same or similar to those previously described with reference to FIGS. 1 to 5. Therefore, for convenience of description, the description will focus on the differences between the semiconductor package 2 of FIGS. 6 and 7 and the semiconductor package 1 of FIGS. 1 to 5 described above.

Referring to FIGS. 6 and 7, the semiconductor package 2 may include a package substrate 100, a die 200, a socket 300, a stack structure 310, a cover 400, a jig JIG, and an optical input/output device 500.

The package substrate 100 may include, for example, a printed circuit board (PCB). As an example, the package substrate 100 may include a core substrate or a coreless substrate. The package substrate 100 may include a plurality of embedded insulating layers and conductive routing. The package substrate 100 may include a first surface 101 and a second surface 102 opposite the first surface 101. The first surface 101 may be an upper surface of the package substrate 100 and may be a portion where the die 200 and the stack structure 310 are disposed. Although not illustrated in FIGS. 6 and 7, the second surface 102 may be a lower surface of the package substrate 100, where the external connection terminal 120 of FIG. 4 is disposed.

The die 200 may be disposed on the first surface 101 of the package substrate 100. In an embodiment, the die 200 may include a logic chip such as ASIC or AP. However, this only corresponds to an embodiment, and the type of die 200 may not be limited thereto. Although only one die 200 is illustrated in FIGS. 6 and 7, in other embodiments, two or more dies 200 may be included in the semiconductor package 2. This may vary depending on the design of the semiconductor package 2 to be implemented.

The stack structure 310 may be laterally spaced apart from the die 200 and disposed on the first surface 101 of the package substrate 100. A plurality of stack structures 310 may be provided. The plurality of stack structures 310 may be arranged in an annular shape with the die 200 in a center. For example, eight stack structures 310 may be provided as illustrated in FIG. 7. Eight stack structures 310 may be arranged two at a time on each side of the package substrate 100. However, in the inventive concept, the number and planar arrangement of the stack structures 310 not limited thereto. The stack structures 310 may be provided in a number of eight or fewer or eight or more, and may be disposed on only one side of the die 200 from a plan view.

The stack structure 310 may include the intermediate substrate 320, the optical integrated circuit chip 330, the electronic integrated circuit chip 340, and the clamp 350, as illustrated in FIG. 5. As an example, the intermediate substrate 320 may include an interposer or a redistribution layer (RDL). The intermediate substrate 320 may include a plurality of embedded insulating layers and conductive routing. The intermediate substrate 320 may be omitted. When the intermediate substrate 320 is omitted, a lowermost optical integrated circuit chip 330 may be directly mechanically and electrically coupled to the socket 300. This may vary depending on the design of the semiconductor package 2 to be implemented.

The optical integrated circuit chip 330 may be disposed on the intermediate substrate 320. The optical integrated circuit chip 330 may include a circuit in which an optical integrated circuit element and an electrical integrated circuit element are combined. The optical integrated circuit chip 330 may refer to a device for converting optical signals to electrical signals or/and converting electrical signals to optical signals. Although not illustrated in FIGS. 6 and 7, the optical integrated circuit chip 330 of the semiconductor package 2 may include the through via TSV, the bonding pad BP, and the groove GRV of FIG. 4.

A plurality of optical integrated circuit chips 330 may be provided. The plurality of optical integrated circuit chips 330 may be sequentially stacked in a vertical direction. Two optical integrated circuit chips 330 adjacent to each other above and below may be mechanically and electrically coupled to each other through the bonding pads BP. As an example, two optical integrated circuit chips 330 may be hybrid-bonded to each other. According to this method, the optical integrated circuit chips 330 may be sequentially stacked in the vertical direction.

The electronic integrated circuit chip 340 and the clamp 350 may be arranged on an uppermost optical integrated circuit chip 330. The electronic integrated circuit chip 340 may include a circuit having electrical integrated circuit elements. The electronic integrated circuit chip 340 may be contrasted with the optical integrated circuit chip 330 in that the electronic integrated circuit chip 340 includes only circuits with electrical integrated circuit elements. The electronic integrated circuit chip 340 may be mechanically and electrically connected to the uppermost optical integrated circuit chip 330. The clamp 350 may perform a function to help ensure that optical fibers coming from the optical input/output device 500 are properly fixed to the stack structure 310. The clamp 350 may be arranged on an edge portion of the stack structure 310.

The socket 300 may be arranged between the package substrate 100 and the stack structure 310. The socket 300 may be arranged only on the first surface 101 of the package substrate 100. The socket 300 may mechanically and electrically couple the package substrate 100 and the stack structure 310 to each other. The socket 300 may include, for example, an LGA type. When the socket 300 is an LGA type, the socket 300 may include pins rising in a direction toward the stack structure 310, and pads (e.g., contacts) that may be electrically connected to the pins may be arranged on the lower surface of the intermediate substrate 320 of the stack structure 310. Alternatively, the socket 300 may include, for example, a PGA type. When the socket 300 is a PGA type, pins rising toward the socket 300 may be disposed on the lower surface of the intermediate substrate 320 of the stack structure 310, and the socket 300 may include grooves (e.g., contacts) that may accommodate the pins of the intermediate substrate 320. When the intermediate substrate 320 is not used, then pins or grooves/pads may be formed on the lowermost optical integrated circuit chip 330 of the stack structure 310.

The socket 300 may be mechanically and electrically connected to the package substrate 100 through second connection terminals 315. The second connection terminals 315 may include solder bumps and/or solder balls. Alternatively, the second connection terminals 315 may be omitted and the socket 300 may be directly attached to the first surface 101 of the package substrate 100.

The cover 400 may cover a portion of the stack structure 310. The cover 400 may include a cover opening 400H. The cover opening 400H may penetrate through the cover 400. The cover opening 400H may have a rectangular shape from a plan view. However, this only corresponds to an embodiment, and the planar shape of the cover opening 400H may have various shapes, such as a polygonal, circular, or elliptical ring shape. At least a portion of the electronic integrated circuit chip 340 and at least a portion of the clamp 350 may be exposed to the outside through the cover opening 400H. In this embodiment, the cover 400 may contact and cover an outer portion of a top surface of the stack structure 310 including a top surface of the electronic integrated circuit chip 340 and clamp 350, and may also cover and contact side surfaces of the electronic integrated circuit chip 340 and clamp 350. For example, the cover 400 may have a frame shape (e.g., a square or rectangular frame shape).

The jig JIG may be arranged next to the socket 300. The cover 400 may be mechanically connected to the jig JIG, so that the jig JIG may control the opening and closing of the cover 400. A method whereby the stack structure 310 is coupled to the socket 300 may include an operation of opening the cover 400 through the jig JIG, an operation of arranging the stack structure 310 on the socket 300, and an operation of covering the stack structure 310 by the cover 400 through the jig JIG. The cover 400 and the jig JIG may be, for example, a push pull type cover.

The optical input/output device 500 may be connected to the stack structure 310 and may extend away from the package substrate 100. The optical input/output device 500 may include optical fibers entering the optical input/output device 500 from the outside and optical fibers going out from (e.g., exiting) the optical input/output device 500 and extending to the stack structure 310. Each of the optical fibers going out from the optical input/output device 500 to the stack structure 310 may be disposed within one of the plurality of grooves GRV. The optical fibers may be connected to the optical integrated circuit chips 330 through the grooves GRV.

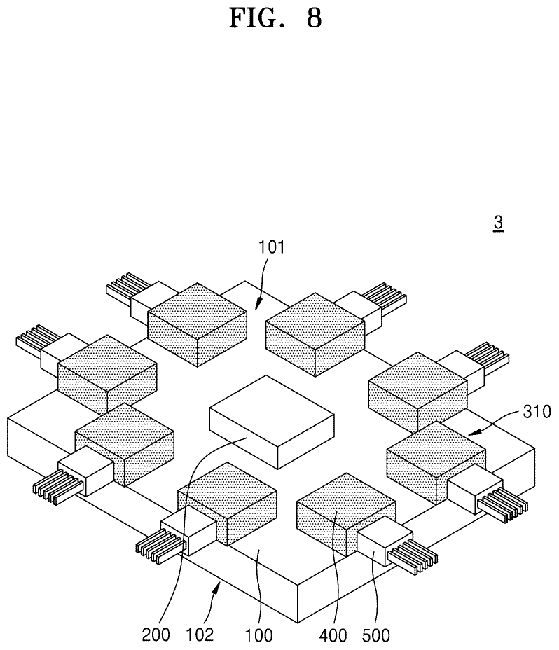

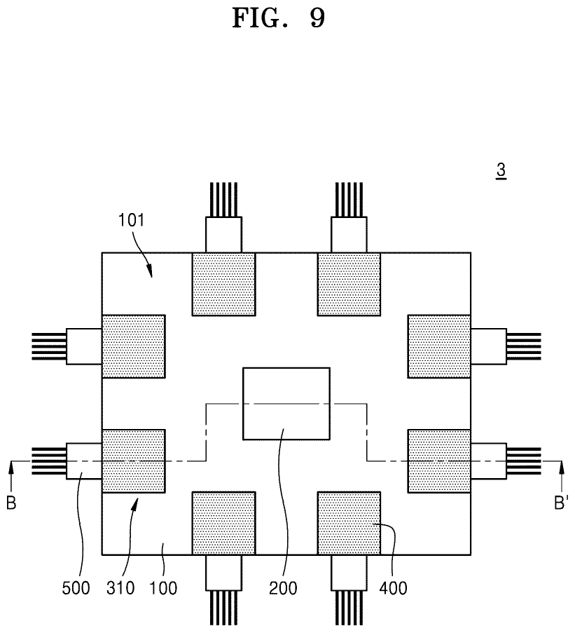

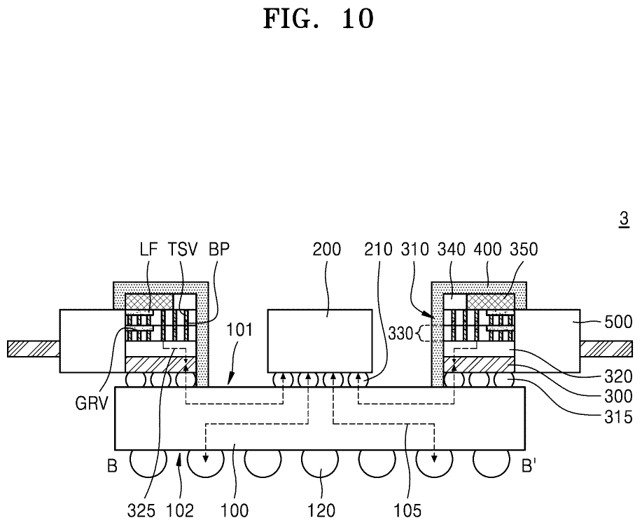

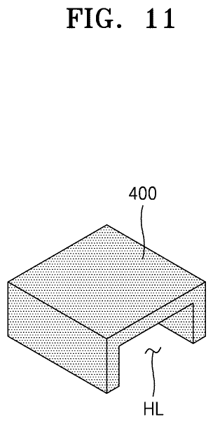

FIG. 8 is a perspective view illustrating a semiconductor package according to an embodiment. FIG. 9 is a plan view illustrating the semiconductor package of FIG. 8, illustrating a first surface of a package substrate. FIG. 10 is a cross-sectional view taken along line B-B′ of FIG. 9 according to an embodiment. FIG. 11 is a perspective view illustrating a cover according to an embodiment.

Most of the components constituting a semiconductor package 3 described below and the materials constituting the components are substantially the same or similar to those previously described with reference to FIGS. 1 to 5. Therefore, for convenience of description, the description will focus on the differences between the semiconductor package 3 of FIGS. 8 to 11 and the semiconductor package 1 of FIGS. 1 to 5 described above.

Referring to FIGS. 8 to 11, the semiconductor package 3 may include a package substrate 100, a die 200, a socket 300, a stack structure 310, a cover 400, and an optical input/output device 500.

The package substrate 100 may include, for example, a printed circuit board (PCB). As an example, the package substrate 100 may include a core substrate or a coreless substrate. The package substrate 100 may include a plurality of embedded insulating layers and conductive routing. The package substrate 100 may include a first surface 101 and a second surface 102 opposite the first surface 101. The first surface 101 may be an upper surface of the package substrate 100 and may be a portion where the die 200 and the stack structure 310 are disposed. The second surface 102 may be a lower surface of the package substrate 100 and a portion where the external connection terminal 120 of FIG. 4 is disposed.

The die 200 may be disposed on the first surface 101 of the package substrate 100. In an embodiment, the die 200 may include a logic chip such as ASIC or AP. However, this only corresponds to an embodiment, and the type of die 200 may not be limited thereto. Although only one die 200 is illustrated in FIGS. 8-11, in other embodiments, two or more dies 200 may be included in the semiconductor package 3. This may vary depending on the design of the semiconductor package 3 to be implemented.

The stack structure 310 may be laterally spaced apart from the die 200 and disposed on the first surface 101 of the package substrate 100. A plurality of stack structures 310 may be provided. The plurality of stack structures 310 may be arranged in an annular shape with the die 200 in a center. For example, eight stack structures 310 may be provided as illustrated in FIG. 9. Eight stack structures 310 may be arranged two at a time on each side of the package substrate 100. However, in the inventive concept, the number and planar arrangement of the stack structures 310 may not be limited thereto. The stack structures 310 may be provided in a number of eight or fewer or eight or more, and may be disposed on only one side of the die 200 from a plan view.

The stack structure 310 may include the intermediate substrate 320, the optical integrated circuit chip 330, the electronic integrated circuit chip 340, and the clamp 350, as illustrated in FIG. 5. As an example, the intermediate substrate 320 may include an interposer or a redistribution layer (RDL). The intermediate substrate 320 may include a plurality of embedded insulating layers and conductive routing. The intermediate substrate 320 may be omitted. When the intermediate substrate 320 is omitted, a lowermost optical integrated circuit chip 330 may be directly mechanically and electrically coupled to the socket 300. This may vary depending on the design of the semiconductor package 2 to be implemented.

The optical integrated circuit chip 330 may be disposed on the intermediate substrate 320. The optical integrated circuit chip 330 may include a circuit in which an optical integrated circuit element and an electrical integrated circuit element are combined. The optical integrated circuit chip 330 may refer to a device for converting optical signals to electrical signals or/and converting electrical signals to optical signals. The optical integrated circuit chip 330 of the semiconductor package 3 may include the through via TSV, the bonding pad BP, and the groove GRV of FIG. 4.

A plurality of optical integrated circuit chips 330 may be provided. The plurality of optical integrated circuit chips 330 may be sequentially stacked in a vertical direction. Two optical integrated circuit chips 330 adjacent to each other above and below may be mechanically and electrically coupled to each other through the bonding pads BP. As an example, two optical integrated circuit chips 330 may be hybrid-bonded to each other. According to this method, the optical integrated circuit chips 330 may be sequentially stacked in the vertical direction.

The electronic integrated circuit chip 340 and the clamp 350 may be arranged on the uppermost optical integrated circuit chip 330. The electronic integrated circuit chip 340 may include a circuit having electrical integrated circuit elements. The electronic integrated circuit chip 340 may be contrasted with the optical integrated circuit chip 330 in that the electronic integrated circuit chip 340 includes only circuits with electrical integrated circuit elements. The electronic integrated circuit chip 340 may be mechanically and electrically connected to the uppermost optical integrated circuit chip 330. The clamp 350 may perform a function to help ensure that optical fibers coming from the optical input/output device 500 are properly fixed to the stack structure 310. The clamp 350 may be arranged on an edge portion of the stack structure 310.

The socket 300 may be arranged between the package substrate 100 and the stack structure 310. The socket 300 may be arranged only on the first surface 101 of the package substrate 100. The socket 300 may mechanically and electrically couple the package substrate 100 and the stack structure 310 to each other. The socket 300 may include, for example, an LGA type. When the socket 300 is an LGA type, the socket 300 may include pins rising in a direction toward the stack structure 310, and pads that may be electrically connected to the pins may be arranged on the lower surface of the intermediate substrate 320 of the stack structure 310. Alternatively, the socket 300 may include, for example, a PGA type. When the socket 300 is a PGA type, pins rising toward the socket 300 may be disposed on the lower surface of the intermediate substrate 320 of the stack structure 310, and the socket 300 may include grooves that may accommodate the pins of the intermediate substrate 320.

The socket 300 may be mechanically and electrically connected to the package substrate 100 through second connection terminals 315. The second connection terminals 315 may include solder bumps and/or solder balls. Alternatively, the second connection terminals 315 may be omitted and the socket 300 may be directly attached to the first surface 101 of the package substrate 100.

The cover 400 may completely cover three of four side surfaces of the stack structure 310. As illustrated in FIGS. 8-11, a depth of the cover 400 may be greater than a depth of the cover 400 of the semiconductor package 1 described with reference to FIGS. 1 to 5. The cover 400 may include a cover hole HL on one side surface thereof. The stack structure 310 and the optical input/output device 500 may be connected to each other through the cover hole HL. For example, three side surfaces of the cover 400 may contact the first surface 101 of the package substrate 100. The cover 400 may include a full cover type. The cover 400 may function to protect the stack structure 310 from external impacts and foreign substances. Accordingly, the lifespan of the optical integrated circuit chip 330 and the electronic integrated circuit chip 340 of the stack structure 310 may be increased.

The optical input/output device 500 may be connected to the stack structure 310 and may extend away from the package substrate 100. The optical input/output device 500 may include optical fibers entering the optical input/output device 500 from the outside and optical fibers going out from (e.g., exiting) the optical input/output device 500 and extending to the stack structure 310. Each of the optical fibers going out from the optical input/output device 500 to the stack structure 310 may be disposed within one of the plurality of grooves GRV. Each of the optical fibers may be connected to the optical integrated circuit chips 330 through the grooves GRV.

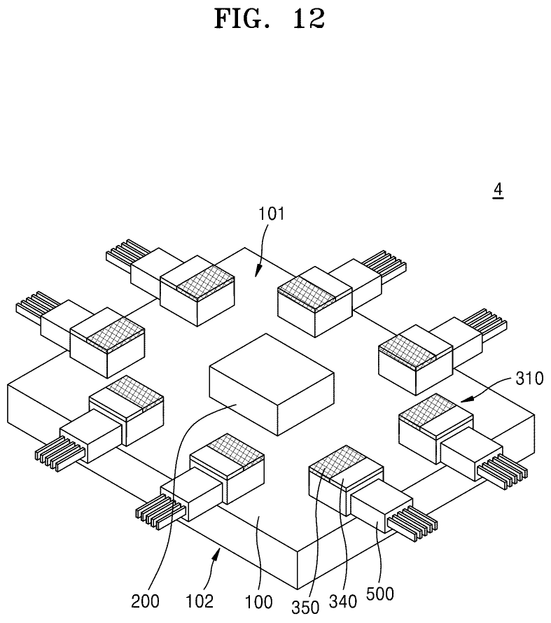

FIG. 12 is a perspective view illustrating a semiconductor package according to an embodiment.

Most of the components constituting a semiconductor package 4 described below and the materials constituting the components are substantially the same or similar to those previously described with reference to FIGS. 1 to 5. Thus, for convenience of description, the description will focus on the differences between the semiconductor package 4 of FIG. 12 and the semiconductor package 1 of FIGS. 1 to 5 described above.

Referring to FIG. 12, the semiconductor package 4 may include a package substrate 100, a die 200, a socket 300, a stack structure 310, and an optical input/output device 500.

In the semiconductor package 4 according to an embodiment, the cover 400 of the semiconductor package 1 of FIGS. 1 to 5 may be omitted. As the cover 400 is omitted, an upper surface and side surfaces of the stack structure 310 may be exposed to the outside. If the cover 400 is omitted, there is no need to remove the cover 400 when replacing the stack structure 310, thus making it easier to replace worn optical integrated circuit chips 330 or worn electronic integrated circuit chips 340.

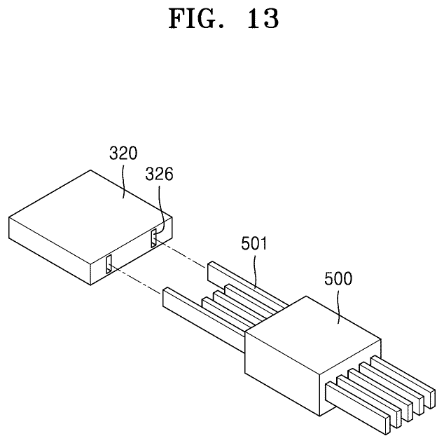

FIG. 13 is a perspective view illustrating an intermediate substrate and an optical input/output port, according to an embodiment.

Referring to FIG. 13, the optical input/output device 500 according to an embodiment may further include an alignment pin 501. The intermediate substrate 320 may include an alignment hole 326 in one side surface thereof. The alignment pin 501 of the optical input/output device 500 may be inserted into the alignment hole 326 of the intermediate substrate 320, facilitating pre-alignment between the optical fibers of the optical input/output device 500 and the optical integrated circuit chip 330 of the stack structure 310. A plurality of alignment pins 501 may be used (e.g., 2 pins), as depicted in FIG. 13. The alignment pins 501 of the optical input/output device 500 may facilitate optical alignment between the optical fibers and the optical integrated circuit chip 330. The optical input/output device 500 may be described as an optical input/output connector or an optical input/output plug.

While the inventive concept has been particularly shown and described with reference to embodiments thereof, it will be understood that various changes in form and details may be made therein without departing from the spirit and scope of the following claims.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

What is claimed is:

1. A semiconductor package comprising:
a package substrate including a first surface and a second surface opposite the first surface;
a die disposed on the first surface of the package substrate;
a stack structure disposed on the first surface of the package substrate and spaced apart from the die in a horizontal direction; and
a socket disposed between the first surface of the package substrate and the stack structure and coupling the package substrate and the stack structure to each other,
wherein the stack structure includes a plurality of optical integrated circuit chips stacked vertically with each other.

2. The semiconductor package of claim 1, wherein the socket comprises either a land grid array (LGA) type socket or a pin grid array (PGA) type socket.

3. The semiconductor package of claim 1, wherein the plurality of optical integrated circuit chips stacked vertically with each other include two optical integrated circuit chips vertically adjacent to each other and hybrid-bonded with each other.

4. The semiconductor package of claim 1, wherein the stack structure further comprises an electronic integrated circuit chip disposed on an uppermost optical integrated circuit chip among the plurality of optical integrated circuit chips.

5. The semiconductor package of claim 4, wherein:
each of the optical integrated circuit chips comprises through vias, and
the electronic integrated circuit chip and the uppermost optical integrated circuit chip among the plurality of optical integrated circuit chips are electrically connected to each other through the through vias.

6. The semiconductor package of claim 1, further comprising an optical input/output device coupled to the stack structure and spaced apart from the die,
wherein each of the optical integrated circuit chips comprises a groove recessed downward from an upper surface of each optical integrated circuit chip, and
each optical integrated circuit chip and a respective optical input/output device are connected to each other through the groove.

7. The semiconductor package of claim 1, further comprising an optical input/output connector spaced apart from the die with the plurality of optical integrated circuit chips therebetween, the optical input/output device including an alignment pin,
wherein the stack structure further comprises an intermediate substrate which is disposed between the socket and a lowermost optical integrated circuit chip among the plurality of optical integrated circuit chips and includes an alignment hole, and
the alignment pin of the optical input/output connector is coupled to the alignment hole of the intermediate substrate.

8. The semiconductor package of claim 1, further comprising a cover covering at least a portion of the stack structure.

9. The semiconductor package of claim 8, wherein the cover includes a cover opening penetrating through a surface of the cover, and
at least a portion of an upper surface of the stack structure is exposed to the outside of the semiconductor package through the cover opening.

10. The semiconductor package of claim 8, wherein the cover contacts the first surface of the package substrate.

11. The semiconductor package of claim 10, wherein:
the cover includes a cover hole in one side surface of the cover, and
the semiconductor package further comprises an optical input/output connector spaced apart from the die with the stack structure therebetween, and
the optical input/output connector is connected to the optical integrated circuit chips through the cover hole.

12. The semiconductor package of claim 1, further comprising a plurality of connection terminals disposed between the first surface of the package substrate and the socket,
wherein the socket is connected to the package substrate through the plurality of connection terminals, and
each connection terminal of the plurality of connection terminals comprises a solder ball or solder bump.

13. The semiconductor package of claim 1, wherein the socket contacts the first surface of the package substrate.

14. A semiconductor package comprising:
a package substrate including a first surface and a second surface opposite the first surface;
a die disposed on the first surface of the package substrate;
external connection terminals disposed on the second surface of the package substrate;
a stack structure disposed on the first surface of the package substrate and spaced apart from the die in a horizontal direction, the stack structure including a plurality of optical integrated circuit chips stacked vertically with each other;
a socket disposed between the stack structure and the first surface of the package substrate and coupling the package substrate to the stack structure; and
an optical input/output connector coupled to each of the optical integrated circuit chips.

15. The semiconductor package of claim 14, wherein the external connection terminals comprise solder balls.

16. The semiconductor package of claim 14, wherein the socket comprises either a land grid array (LGA) type socket or a pin grid array (PGA) type socket.

17. The semiconductor package of claim 16, wherein:
the socket comprises an LGA type socket, and
the semiconductor package further comprises a cover covering at least a portion of the stack structure,
wherein the cover is coupled to the socket through a bolt.

18. The semiconductor package of claim 14, wherein each of the optical integrated circuit chips comprises:
a body;
a through via penetrating the body; and
bonding pads disposed on an upper surface and a lower surface of the body,
wherein the through via is connected to one of the bonding pads.

19. A semiconductor package comprising:
a package substrate including a first surface and a second surface opposite the first surface;
a die disposed on the first surface of the package substrate and connected to the package substrate through a connection terminal;
a stack structure disposed on the first surface of the package substrate and spaced apart from the die in a horizontal direction; and
a cover covering at least a portion of the stack structure;
an optical input/output connector spaced apart from the die with the stack structure therebetween; and
a socket disposed between the first surface of the package substrate and the stack structure and coupling the package substrate and the stack structure to each other,
wherein the stack structure comprises:
a plurality of optical integrated circuit chips stacked vertically with each other; and
an electronic integrated circuit chip on an uppermost optical integrated circuit chip among the plurality of optical integrated circuit chips,
wherein the uppermost optical integrated circuit chip among the plurality of optical integrated circuit chips and the electronic integrated circuit chip are electrically connected to each other.

20. The semiconductor package of claim 19, wherein each of the optical integrated circuit chips comprises a groove recessed downward from an upper surface thereof, and
each optical input/output device includes an optical fiber disposed in the groove.
